(19) United States
(12) Patent Application Publication
(10) Pub. No.: US 2026/0347173 A1
(43) Pub. Date: Nov. 5, 2026

(54) SEMICONDUCTOR STRUCTURE AND METHOD OF FORMING THE SAME

(71) Applicant: Agency for Science, Technology and Research, Singapore (SG)

(72) Inventors: Jaibir Sharma, Singapore (SG); Jiaqiang Eldwin Ng, Singapore (SG); Sagnik Ghosh, Singapore (SG); Srinivas Merugu, Singapore (SG)

(21) Appl. No.: 19/124,564

(22) PCT Filed: Oct. 17, 2023
(86) PCT No.: PCT/SG2023/050701

§ 371 Date: Apr. 25, 2025

(30) Foreign Application Priority Data
Oct. 27, 2022 (SG) 10202251515W

(51) Int. Cl. B81C 1/00; B81B 1/00

(52) U.S. Cl. CPC B81C 1/00047; B81B 1/002; B81B 2203/0315; B81C 2201/0126; B81C 2201/0132

(57) ABSTRACT

A method of forming a semiconductor structure. The method may include forming a plurality of openings in a substrate. The plurality of openings may extend from a surface of the substrate into the substrate. Each of the plurality of openings may at least partially be defined by a side wall and may include a portion closer to the surface of the substrate and another portion further away from the surface of the substrate. A lateral dimension of at least one of the plurality of openings may increase with distance from the surface of the substrate. The method may include annealing the substrate after forming the plurality of openings, thereby forming a buried cavity and a membrane over the buried cavity, the buried cavity having a height greater than 3 μm and greater than a thickness of the membrane.

### CROSS-REFERENCE TO RELATED APPLICATION

This application claims the benefit of priority of Singapore application No. 10202251515W filed Oct. 27, 2022, the contents of it being hereby incorporated by reference in its entirety for all purposes.

### TECHNICAL FIELD

Various embodiments of this disclosure may relate to a semiconductor structure. Various embodiments of this disclosure may relate to a method of forming a semiconductor structure.

### BACKGROUND

Microelectromechanical system (MEMS) devices have achieved a great attention in last decade due to cutting edge applications, including inertial sensors, Bio-MEMS sensors, and optical MEMS device like scanner, spectrometer, and radio frequency (RF) devices like thin-film bulk acoustic resonators (FBAR), FBAR filters, RF MEMS switches, resonators and thermoelectric infrared sensors. The MEMS devices may be fabricated by bulk micromachining, by surface micromachining or by a lithography, electroplating, and molding (i.e. Lithographie, Galvanoformung, Abformung or LIGA) process. In the surface micromachining process, many layers are deposited and selectively etched to achieve the final MEMS devices. Typical processes for fabricating membranes include (a) using a sacrificial layer followed by the deposition of the silicon for the membrane/structure, and then patterning vents to remove the sacrificial layer underneath to release the silicon structures, (b) fabricating a cavity silicon-on-insulator (CSOI) wafer by first etching a cavity on a first wafer, followed by bonding a second wafer to the first, and grinding down or removing most of the second wafer or (c) forming the main device on the first side of a wafer, followed by flipping the wafer and etching a cavity from the back to form a membrane.

These process have their limitations, often resulting in lower yield, higher cost, or poor performance: (a) a cavity depth limited by the sacrificial material thickness (poor performance), poor dimension control over the release area, as well as extra steps required to seal the cavity; (b) typically higher associated costs with wastage of most of the second wafer and limited bonding yield; (c) poor control over the membrane dimensions, and an open back cavity, and poor ability to scale to smaller dimensions.

Silicon-on-nothing fabrication processes have been demonstrated to create a buried cavity within silicon with good thickness control, excellent dimension control, and scalability. These processes typically involve creating vertical holes via deep reactive ion etching (DRIE) of silicon, followed by an annealing step to allow the silicon atoms to migrate, forming a buried cavity. FIG. 1A is a scanning electron microscopy (SEM) image of a buried cavity formed by a conventional silicon-on-nothing (SON) process. FIG. 1B shows (above) scanning electron microscopy (SEM) images of a conventional silicon-on-nothing process, and (below) a schematic illustrating bidirectional silicon migration process during annealing. FIG. 1C illustrates the silicon migration process to form the buried cavity.

The cavity depth (alternatively referring to as cavity height or Tₚ) formed by this means is typically limited to a maximum of around 2-3 μm. This has a significant disadvantage for many MEMS devices including limiting the maximum displacement or reducing the thermal resistance across the cavity to the substrate. Some MEMS actuators, sensors and piezoelectric ultrasonic micromachined transducers (pMUTs) require large out-of-plane (along z-axis) deflections, which are limited by such shallow cavity. Flexural mode resonators and devices with flexible elements are prone to out-of-plane deflections (along z-axis) due to process induced stress. Such stress induced deflections can stick the device to the substrate due to the shallow cavity.

In addition, other limitations arise from small depth cavity when there is a need to convert a portion of the silicon membrane underneath into oxide. Oxidation on the bottom side of the membrane results in an additional volume of silicon oxide grown into the cavity, which has the effect of narrowing the cavity. Given the already narrow dimensions of the cavity, a deeper cavity is needed to prevent the membrane from touching the bottom of the cavity, annulling the effect of larger thermal resistance. Deeper cavities in silicon membranes have been demonstrated using annealing of porous silicon, but this typically involves a series of fabrication processes to achieve, including doping, passivation, and electrochemical etching to form the porous silicon. Other possibilities of forming the cavities include passivating the vertical sidewalls followed by an isotropic etch, but this also has limitations in the achievable cavity depth as well as the extra process steps required.

FIG. 1D illustrates a state-of-the-art process used to form porous silicon membrane, as well as using the same in a silicon-on-nothing (SON) process to form the membrane and cavity by annealing.

### SUMMARY

Various embodiments may relate to a method of forming a semiconductor structure. The method may include forming a plurality of openings in a substrate. The plurality of openings may extend from a surface of the substrate into the substrate. Each of the plurality of openings may at least partially be defined by a side wall and may include a portion closer to the surface of the substrate and another portion further away from the surface of the substrate. A diameter or lateral dimension of at least one of the plurality of openings may increase with distance from the surface of the substrate such that the portion closer to the surface of the substrate of said at least one of the plurality of openings is narrower than the other portion further away from the surface of the substrate of said at least one of the plurality of openings. The method may include annealing the substrate after forming the plurality of openings, thereby forming a buried cavity and a membrane over the buried cavity, the buried cavity having a height greater than 3 μm (e.g. greater than 3.5 μm) and greater than a thickness of the membrane.

Various embodiments may relate to a semiconductor structure. The semiconductor structure may include a substrate having a buried cavity and a membrane over the buried cavity. The buried cavity may have a height greater than 3 μm (e.g. greater than 3.5 μm) and greater than a thickness of the membrane.

### BRIEF DESCRIPTION OF THE DRAWINGS

In the drawings, like reference characters generally refer to the same parts throughout the different views. The drawings are not necessarily drawn to scale, emphasis instead generally being placed upon illustrating the principles of various embodiments. In the following description, various embodiments of the invention are described with reference to the following drawings.

FIG. 1A is a scanning electron microscopy (SEM) image of a buried cavity formed by a conventional silicon-on-nothing (SON) process.

FIG. 1B shows (above) scanning electron microscopy (SEM) images of a conventional silicon-on-nothing process, and (below) a schematic illustrating bidirectional silicon migration process during annealing.

FIG. 1C illustrates the silicon migration process to form the buried cavity.

FIG. 1D illustrates a state-of-the-art process used to form porous silicon membrane, as well as using the same in a silicon-on-nothing (SON) process to form the membrane and cavity by annealing.

FIG. 2 shows (above) a schematic of a buried cavity formed by a silicon-on-nothing (SON) process, with various parameters such as thickness of membrane (Tₛₒₙ), cavity depth or cavity height (Tₚ) and recess height between membrane and remaining substrate (Tₛₜₑₚ) labelled; and (below) a plot distance (in micrometers or μm) as a function of spacing c between trenches (holes) (in micrometers or μm) illustrating variation of the various parameters with trench or hole spacing.

FIG. 3 shows a general illustration of a method of forming a semiconductor structure according to various embodiments.

FIG. 4 shows a general illustration of a semiconductor structure according to various embodiments.

FIG. 5 illustrates a process of forming a semiconductor structure having a buried deep cavity using a silicon-on-nothing (SON) technique according to various embodiments.

FIG. 6A illustrates conventional processes of forming silicon-on-nothing (SON) structures.

FIG. 6B is a scanning electron microscopy (SEM) image showing the pinch-off phenomenon.

FIG. 6C illustrates the relevant equations that result in the formation of multiple membranes and multiple small cavities in the conventional silicon-on-nothing (SON) process.

FIG. 7A illustrates an ideal case to obtain deeper cavities using the silicon-on-nothing (SON) technique. In this ideal case, only upwards silicon migration should occur.

FIG. 7B illustrates a process of forming a semiconductor structure having a deeper buried cavity using a silicon-on-nothing (SON) technique involving forming openings with negative profile according to various embodiments.

FIG. 7C shows a scanning electron microscopy (SEM) image of a semiconductor structure with a buried deep cavity and a membrane over the buried deep cavity according to various embodiments.

FIG. 7D illustrates the calculation of 2-dimensional (2D) fill factor of an array of square etch holes according to various embodiments.

FIG. 7E illustrates a comparison of migrated silicon volume for vertically etched circular openings (holes) and circular bases (holes) of a negative profile according to various embodiments.

FIG. 7F illustrates an unit cell to compute a 3-dimensional (3D) fill factor based on the 2-dimensional (2D) fill factor, etch depth and angle of negative etch profile according to various embodiments.

FIG. 7G shows a plot of the 3-dimensional fill factor 3DFF_{etchholes} (in percent or %) as a function of the 2-dimensional fill factor 2DFF_{etchholes} (in percent or %) illustrating variation of 3DFF_{etchholes} with 2DFF_{etchholes} of the openings according to various embodiments.

FIG. 7H shows a plot of membrane thickness Tₛₒₙ (in micrometers or μm)/cavity depth Tₚ (in micrometers or μm) as a function of the 3-dimensional fill factor 3DFF_{etchholes} (in percent or %) illustrating variations of Tₛₒₙ and Tₚ with 3DFF_{etchholes} of the openings according to various embodiments.

FIG. 8 illustrates (a) a process of forming a semiconductor structure according to various embodiments; and (b) a comparison between the semiconductor structures formed using a square array of openings and an equilateral triangular array of openings according to various embodiments.

FIG. 9A shows a scanning electron microscopy (SEM) image illustrating experimental results of negative profile silicon etching according to various embodiments.

FIG. 9B shows a schematic illustrating the merging of the etch holes according to various embodiments.

FIG. 10A is a scanning electron microscopy (SEM) image showing the pinch-off phenomenon.

FIG. 10B is a scanning electron microscopy (SEM) image showing a conventional silicon-on-nothing structure.

FIG. 11A shows a schematic of the substrate in which negative profile openings (holes) are formed with different spacings between neighboring or adjacent openings (holes), leading to merging of the openings (holes) at different depths according to various embodiments.

FIG. 11B shows a schematic of the substrate with different thicknesses of membranes formed corresponding to the different groups of openings (holes) with different spacings according to various embodiments.

FIG. 11C shows a scanning electron microscopy (SEM) image of the semiconductor structure formed from openings (holes) with small pitch according to various embodiments.

FIG. 11D shows a scanning electron microscopy (SEM) image of the semiconductor structure formed from openings (holes) with medium pitch according to various embodiments.

FIG. 12 shows the steps involved in the design of a semiconductor structure including a buried cavity and a membrane above the buried cavity according to various embodiments.

FIG. 13 shows a table comparing the conventional silicon-on-nothing (SON) process and various embodiments.

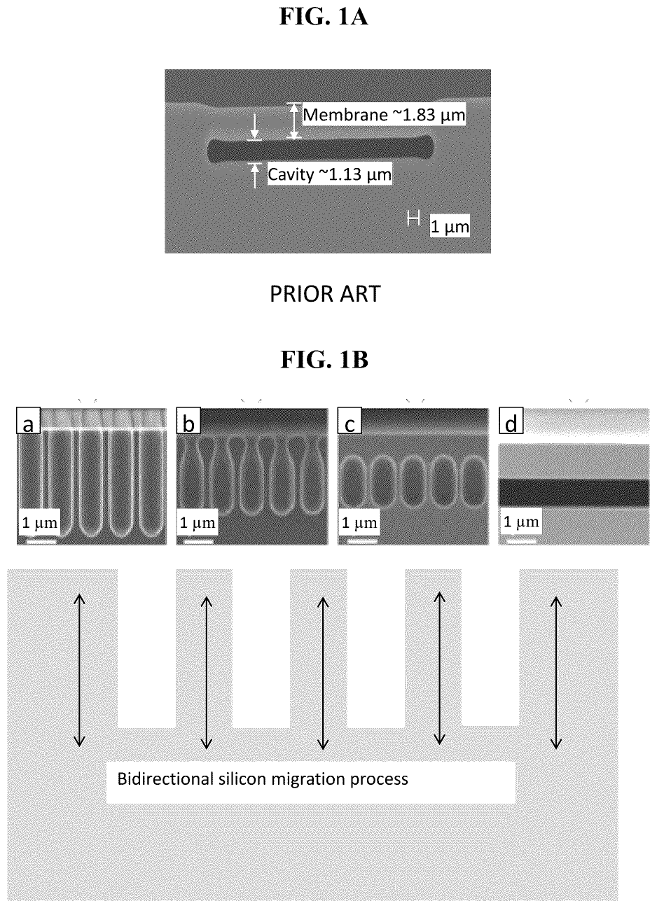

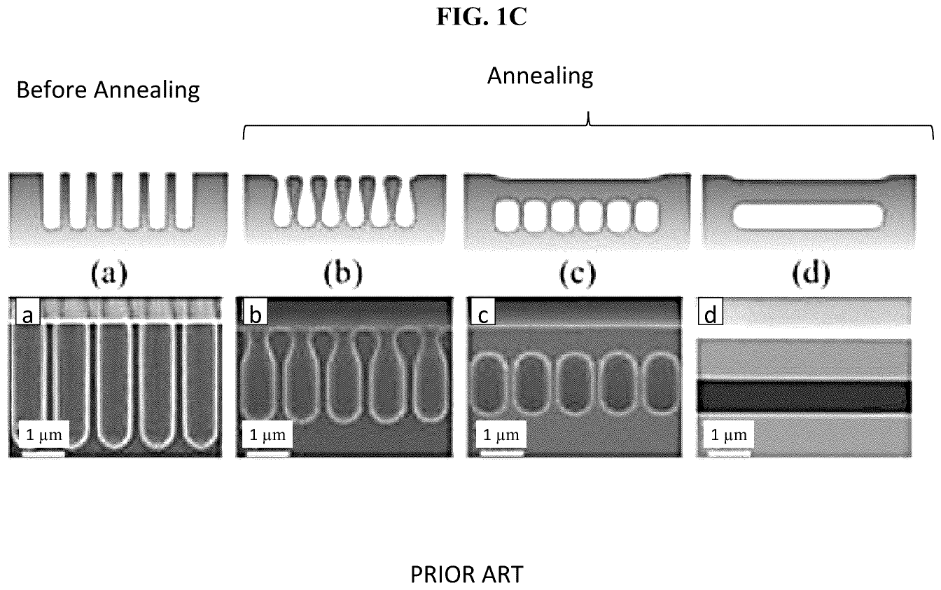

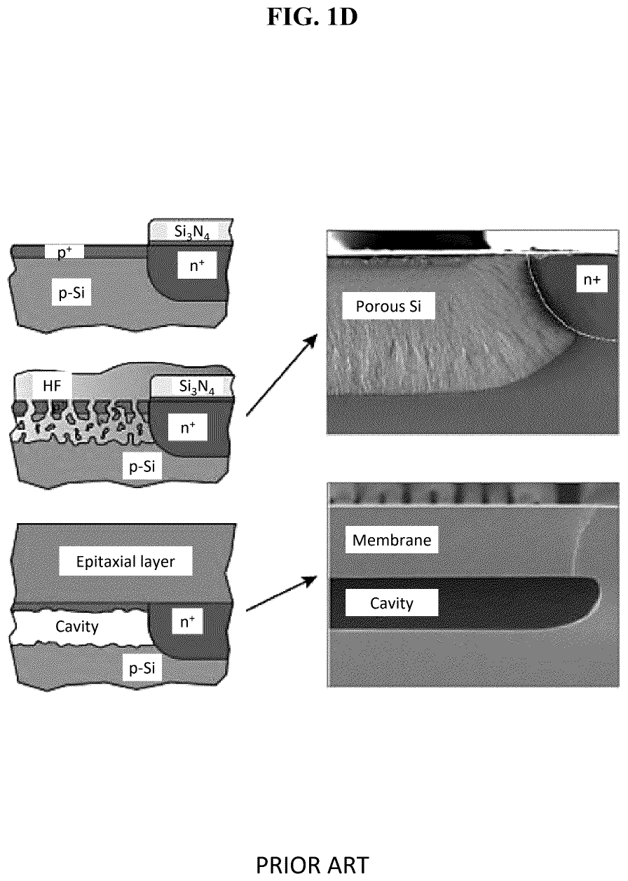

### DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance, e.g. within 10% of the specified value.

As used herein, the term “and/or” includes any and all combinations of one or more of the associated listed items.

By “comprising” it is meant including, but not limited to, whatever follows the word “comprising”. Thus, use of the term “comprising” indicates that the listed elements are required or mandatory, but that other elements are optional and may or may not be present.

By “consisting of” is meant including, and limited to, whatever follows the phrase “consisting of”. Thus, the phrase “consisting of” indicates that the listed elements are required or mandatory, and that no other elements may be present.

Embodiments described in the context of one of the semiconductor structures/substrates are analogously valid for the other semiconductor structures/substrates, embodiments described in the context of a method are analogously valid for a semiconductor structure/substrate, and vice versa.

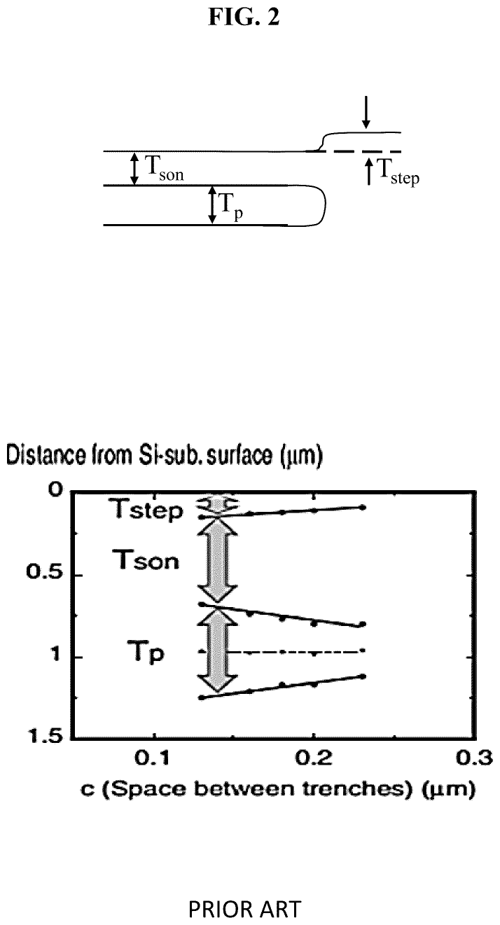

FIG. 2 shows (above) a schematic of a buried cavity formed by a silicon-on-nothing (SON) process, with various parameters such as thickness of membrane (Tₛₒₙ), cavity depth or cavity height (Tₚ) and recess height between membrane and remaining substrate (Tₛₜₑₚ) labelled; and (below) a plot distance (in micrometers or μm) as a function of spacing c between trenches (holes) (in micrometers or μm) illustrating variation of the various parameters with trench or hole spacing. The plot indicates a cavity depth or cavity height (Tₚ) of more than 1.2 μm requires a trench or hole spacing of smaller than 100 nm, which is beyond the scope of conventional photolithography and requires expensive electron beam or e-beam lithography. Further, such a small spacing would make it difficult to etch the holes or trenches using high aspect DRIE. Also, such a fine feature would typically require thin photoresist (PR) to define. However, it is difficult to etch deeper holes or trenches within thin photoresist (PR), and additional hard masks may be required.

From the plot, a thicker membrane is obtained with a more shallow cavity. However, problems as described above will arise. For instance, the bottom surface of the membrane may touch the substrate due to the shallow cavity.

The membrane thickness and cavity depth may be dependent on the two-dimensional (2D) fill factor of the etch holes. In a conventional SON process, during high temperature annealing, silicon may migrate in both upward and downward directions. The deeper etch holes in silicon (Si) may result in multiple cavities while the shallower etch holes may result in a limited cavity depth.

Various embodiments may relate to a process in which both 2D fill factor (along x-y plane) and amount of silicon along the thickness direction (z-axis) may be tuned to fabricate thinner membranes with deeper cavities. Various embodiments may involve a negative profile etching or etch, e.g. negative profile DRIE etching. The amount of silicon (Si) along the thickness direction (z-axis) may be controlled by the negative profile DRIE etching. The post-SON cavity depth may not be governed by conventional migration equations as the Si distribution does not remain regular due to negative etch profile. The silicon migration may be enhanced in the upward direction due to gradual increase of etched area in conical shape and merging of etch holes at bottom due to negative profile DRIE etching while the migration of Si along downward direction may be inhibited. This may result in a deeper cavity (i.e. a buried cavity with increased height). Various embodiments may only require normal lithographic tools as the critical dimensions (CD) are not very small in order to form the deeper buried cavity.

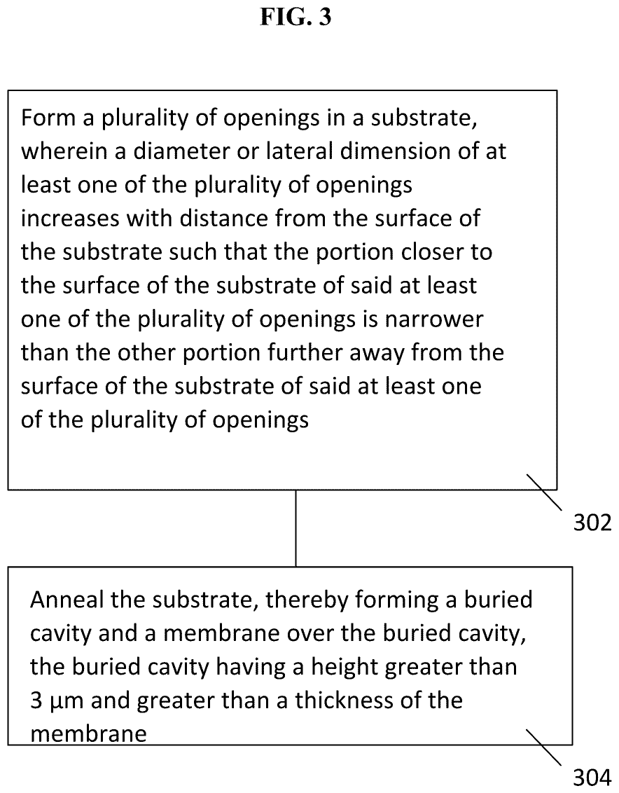

FIG. 3 shows a general illustration of a method of forming a semiconductor structure according to various embodiments. The method may include, in 302, forming a plurality of openings in a substrate. The plurality of openings may extend from a surface of the substrate into the substrate. Each of the plurality of openings may at least partially be defined by a side wall and may include a portion closer to the surface of the substrate and another portion further away from the surface of the substrate. A diameter or lateral dimension of at least one of the plurality of openings may increase with distance from the surface of the substrate such that the portion closer to the surface of the substrate of said at least one of the plurality of openings is narrower than the other portion further away from the surface of the substrate of said at least one of the plurality of openings. The method may include, in 304, annealing or heating the substrate after forming the plurality of openings, thereby forming a buried cavity and a membrane over the buried cavity (alternatively referred to as buried deep cavity), the buried cavity having a height (Tₚ) greater than 3 μm (e.g. greater than 3.5 μm) and greater than a thickness of the membrane (Tₛₒₙ).

In other words, the method may include forming openings on a substrate. One or more of the openings (alternatively referred to as etch holes, holes or trenches) may have a negative profile (also referred to as negative/tapered etch profile holes/openings/trenches), such that the upper part(s) of said one or more openings being narrower than the lower part(s). The method may further include heating the substrate with the openings such that the openings merge to form a buried cavity, i.e. a cavity fully enclosed by the substrate and alternatively referred to as “deep cavity”. The portion of the substrate above the buried cavity may be referred to as a membrane. The buried cavity may have a height (also referred to as depth) greater than 3 μm or 3.5 μm. The height of the buried cavity may be greater than a thickness of the membrane (i.e. a ratio of the thickness of the membrane to a height of the buried cavity is less than 1).

Various embodiments may provide a method to fabricate a semiconductor structure having a deep buried cavity. Having a deep buried cavity (i.e. height of the cavity being greater than 3 μm or 3.5 μm, and greater than a thickness of the membrane) may address many of the issues as described above. For instance, a deep cavity provides a greater allowance for the membrane to deflect without sticking to the bottom of the cavity.

In various embodiments, a thickness of the membrane may be selected from a range from 1 μm to 3 μm, e.g. from 1.5 μm to 1.7 μm. In various embodiments, as mentioned above, the height of the buried cavity may be greater than 3.5 μm, e.g. greater than 5 μm, e.g. 5.5 μm or greater. In various embodiments, the height of the buried cavity may be selected from a range from 5.5 μm to 6.64 μm. In various embodiments, the ratio of the thickness of the membrane to the height of the cavity may be less than 0.5 e.g. less than 0.3.

In various embodiments, forming the plurality of openings may be carried out by an etching process, e.g. reactive ion etching such as deep reactive ion etching (DRIE). The DRIE process may include multiple rounds of etching and deposition. In other words, there may be alternate etching and deposition steps. For the initial round, ions may remove material from a portion of the substrate during etching to form an initial trench, while during deposition, a passivation layer may be formed in the initial trench. The passivation layer may be formed from plasma gases. During the second round, ions may remove the portion of the passivation layer at the bottom of the initial trench as well as material from the underlying portion of the substrate during etching, while the portion of the passivation layer at the side walls of the initial trench remains, thereby protecting the side wall of the initial trench. Deposition in the second round may include forming a further passivation layer (i.e. from the plasma gases). There may be also one or more subsequent rounds of etching and deposition after the second round. In order to form a negative etch profile hole, etching may be carried out with increased voltage bias and/or increased etching time in successive rounds. In other words, the voltage bias used for etching in the second round may be greater than the voltage bias used for etching in the first round, the voltage bias used for etching in the third round may be greater than the voltage bias used for etching in the second round, and so on. Additionally or alternatively, the etching time in the second round may be longer than the etching time in the first round, the etching time in the third round may be longer than the etching time in the second round, and so on. As an example, the etching time in the first round may be selected from a range of 5-10 s, the etching time in the second round may be selected from a range of 11-15 s, the etching time in the third round may be selected from a range of 16-20 s etc.

In various embodiments, the method may also include providing a mask over the substrate before forming the plurality of openings. The mask may include a suitable photoresist (PR) material.

In various embodiments, each of the plurality of openings may include a bottom surface such that the side wall extends between the surface of the substrate and the bottom surface.

As mentioned above, said at least one of the plurality of openings may have a negative profile. The diameter or lateral dimension of said at least one of the plurality of openings may increase monotonically with distance from the surface of the substrate. There may be a gradual widening of the opening with increasing distance from the surface of the substrate. In various embodiments, the bottom surface (of said at least one of the plurality of openings) may have a size at least 1.5 times greater than a size of the opening at the surface of the substrate.

In various embodiments, the bottom surface of each of the plurality of openings and/or a cross-sectional area of each of the plurality of openings at the surface of the substrate may be of a circular, hexagonal or square shape.

In various embodiments, the side wall defining said at least one of the plurality of openings may form an angle (Φ) in a range of greater than 90° to smaller than 120° with respect to the surface of the substrate, i.e. 120°>Φ>90°.

In various embodiments, a diameter or lateral dimension of one or more remaining openings of the plurality of openings may also increase with distance from the surface of the substrate. The portion closer to the surface of the substrate of each of the one or more remaining openings may be narrower than the other portion further away from the surface of the substrate of each of the one or more remaining openings.

In various embodiments, a diameter or lateral dimension of each opening of the plurality of openings may increase with distance from the surface of the substrate (such that the portion closer to the surface of the substrate (i.e. the upper part) of each of the plurality of openings is narrower than the other portion further away from the surface of the substrate (i.e. the lower part) of each of the plurality of openings). Each of the plurality of openings may substantially be of a frustum shape. Heights of the lower parts of the openings may be greater than heights of the upper parts of the plurality of openings.

In various embodiments, an aspect ratio of a depth of each of the plurality of openings (h_{etch}) relative to a diameter or lateral dimension of each of the plurality of openings (dₜₒₚ) at the surface of the substrate may be selected from a range of greater than 13 to smaller than 25, i.e.

$$13 < \frac{{h}_{etch}}{{d}_{top}} < 25 .$$

For instance, a depth of each opening of the plurality of openings may be selected from a range between 3 μm and 15 μm. Such a depth may be applicable for an opening of having a diameter selected from a range from about 0.3 μm to about 1.0 μm on the surface of the substrate.

In various embodiments, the plurality of openings may be equally spaced apart.

In various embodiments, the plurality of openings may be formed such that the plurality of openings merge together to form a cavity (also referred to as an initial cavity). The lower part(s) of at least one of the plurality of openings may be overlapped with the lower part(s) of at least another of the plurality of openings neighboring or adjacent to the at least one of the plurality of openings. In other words, the method may include forming a plurality of openings such that the plurality of openings form an initial cavity (due to the merging of the plurality of openings). Annealing the substrate may then expand the initial cavity to form the buried cavity, which may have a height greater than 3 μm or 3.5 μm.

In various embodiments, a spacing between neighboring or adjacent openings (d_{space}) may be equal to or greater than a diameter or lateral dimension of each of the plurality of openings at the surface of the substrate (dₜₒₚ),

$$i . e . \frac{{d}_{space}}{{d}_{top}} \geq 1.$$

As mentioned above, the critical dimensions of various embodiments may remain not too small such that normal lithographic tools may be used to define the plurality of openings. For instance, in an example, a diameter of each of the plurality of openings/etch holes may be selected from a range from about 0.3 μm to 1.0 μm, while a spacing between neighboring or adjacent openings/etch holes may be selected from a range from 0.3 μm to about 1.0 μm. Various embodiments may involve openings of any suitable diameter/lateral dimension, and spacings between adjacent or neighboring holes of any suitable value.

In various embodiments, a group of three neighboring or adjacent openings of the plurality of openings may be arranged so as to form an equilateral triangle (as seen from a planar view of the surface of the substrate). In various other embodiments, a group of four neighboring or adjacent openings may be arranged so as to form a square or diamond (as seen from a planar view of the surface of the substrate). In other words, the plurality of openings may be in one of more groups, such that each opening in a particular group of the one or more groups may be spaced equally from two or more of the remaining openings in the particular group. The openings in each group may form a shape of an equilateral triangle, a square or a diamond. By forming an equilateral triangle for each group, each opening may be spaced equally from the remaining openings, which may allow the formation of a membrane with smoother underneath surface.

In various embodiments, annealing the substrate may include annealing such that atoms from the substrate migrate to form the membrane. Atoms from a part of the substrate surrounding the plurality of openings may migrate upwards (i.e. towards the surface of the substrate) to form the membrane. In various embodiments, the migration of atoms downwards (i.e. away from the surface of the substrate) may be reduced or prevented. In various embodiments, the method may include removing the photoresist material after forming the openings but before annealing the substrate.

The annealing of the substrate may be carried out via heating in a furnace, or via rapid thermal annealing (RTA). The annealing of the substrate may be carried out at any suitable temperature selected from a range from 500 °C to 1300 °C. The annealing of the substrate may be carried out under pressure selected from a range from 10-7 to 10-4 torrs. The annealing of the substrate may be carried out in the presence of a suitable gas or gases, such as hydrogen gas (H₂), argon gas (Ar) and/or nitrogen gas (N₂).

A thickness of the membrane formed may decrease with increasing 3D fill factor. A thickness of the membrane formed may be dependent on the 3D fill factor, which may in turn be dependent on a depth of the plurality of openings (h_{etch}), a 2D fill factor (2DFF_{etchholes}) and an angle between the surface of the substrate and the side wall (Φ=180°−θ). The 2D fill factor (2DFF_{etchholes}) may be dependent on the diameter or lateral dimension of the opening (dₜₒₚ). Additionally, the thickness of the membrane formed may also be dependent on a spacing between neighboring or adjacent openings of the plurality of openings. In other words, the thickness of the membrane formed may be dependent on a depth of the plurality of openings (h_{etch}), the diameter or lateral dimension of the plurality of openings (dₜₒₚ), the angle between the surface of the substrate and the side wall (Φ=180°−θ) of the plurality of openings, and a spacing between neighboring or adjacent openings of the plurality of openings. A thickness of the membrane may decrease as a depth of the plurality of openings increases. The thickness of the membrane may decrease as a diameter or a lateral dimension of the plurality of openings at the surface of the substrate increases. The thickness of the membrane may decrease as an angle between the surface of the substrate and the side wall of each of the plurality of openings decreases. The thickness of the membrane may decrease as a spacing between neighboring or adjacent openings of the plurality of openings decreases.

A height of the buried cavity formed may increase with increasing 3D fill factor. A height of the buried cavity formed may be dependent on the 3D fill factor, which may in turn be dependent on a depth of the plurality of openings (h_{etch}), a 2D fill factor (2DFF_{etchholes}) and an angle between the surface of the substrate, the side wall (Φ180°−θ) and a spacing between neighboring or adjacent openings of the plurality of openings. The 2D fill factor (2DFF_{etchholes}) may be dependent on the diameter or lateral dimension of the opening (dₜₒₚ). Additionally, the height of the buried cavity formed may also be dependent on a spacing between neighboring or adjacent openings of the plurality of openings. In other words, the height of the buried cavity formed may be dependent on a depth of the plurality of openings (h_{etch}), the diameter or lateral dimension of the plurality of openings (dₜₒₚ), the angle between the surface of the substrate and the side walls (Φ=180°−θ) of the plurality of openings, and a spacing between neighboring or adjacent openings of the plurality of openings. A height of the buried cavity may increase as a depth of the plurality of openings increases. The height of the buried cavity may increase as a diameter or a lateral dimension of the plurality of openings at the surface of the substrate increases. The height of the buried cavity may increase as an angle between the surface of the substrate and the side wall of each of the plurality of openings decreases. The height of the cavity may increase as a spacing between neighboring or adjacent openings of the plurality of openings decreases.

In various embodiments, a 3-dimensional fill factor of the openings (3DFF_{etchholes}) may be between 40% and 60%, i.e. 40%<3DFF_{etchholes} <60%.

In various embodiments, the height of the buried cavity may be greater than half of a depth of the plurality of openings.

In various embodiments, the membrane may be recessed from the surface of a portion of the substrate surrounding the membrane.

In various embodiments, the semiconductor structure may be a silicon-on-nothing (SON) structure. In various embodiments, the semiconductor structure may be or may be part of a micro-electromechanical system (MEMs) device.

Various embodiments as described herein may refer to a silicon or silicon-based substrate or wafer, e.g. a bulk-silicon wafer or a silicon-on-insulator (SOI) wafer. In other words, the substrate may include silicon. However, it may also be envisioned that various embodiments may be applicable to a substrate including any other suitable semiconductor material, such as germanium (Ge).

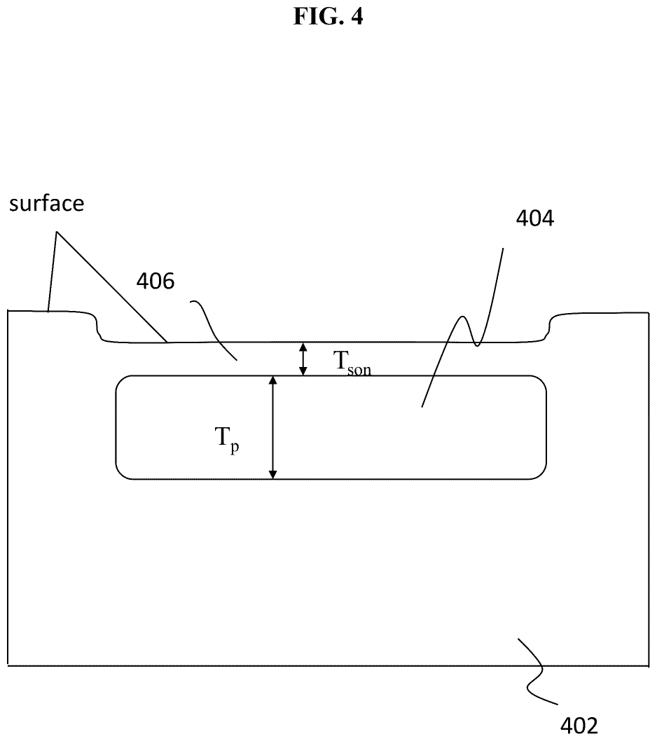

FIG. 4 shows a general illustration of a semiconductor structure according to various embodiments. The semiconductor structure may include a substrate 402 having a buried cavity 404 and a membrane 406 over the buried cavity 404. The buried cavity 404 may have a height (Tₚ) greater than 3 μm (e.g. greater than 3.5 μm) and greater than a thickness (Tₛₒₙ) of the membrane 406.

In other words, various embodiments may relate to a semiconductor structure with a substrate 402 having a fully enclosed cavity 404 below a surface of the substrate 402. A membrane 406 may separate the buried cavity 404 (i.e. fully enclosed cavity) from the surface of the substrate 402. The buried cavity may have a height (also referred to as depth) greater than 3 μm or greater than 3.5 μm. The height of the buried cavity may be greater than a thickness of the membrane. The semiconductor structure illustrated in FIG. 4 may be a final or end semiconductor structure formed after formation of the openings and after the annealing of the substrate.

For avoidance of doubt, FIG. 4 is intended to provide a general illustration of features according to various embodiments, and is not intended to limit the dimensions, shapes, size, orientation etc. of the various features.

In various embodiments, the membrane 406 may be recessed from the surface of a portion of the substrate 402 surrounding the membrane 406.

In various embodiments, the substrate 402 may include any suitable semiconductor material such as silicon or germanium.

In various embodiments, a thickness of the membrane 406 may be selected from a range from 1 μm to 3 μm, e.g. from 1.5 μm to 1.7 μm. In various embodiments, the height of the buried cavity 404 may be greater than 3.5 μm, e.g. greater than 5 μm, e.g. 5.5 μm or greater. In various embodiments, the height of the buried cavity 404 may be selected from a range from 5.5 μm to 6.64 μm. Various embodiments may relate to a semiconductor structure formed by a method as described herein.

Various embodiments may relate to an intermediate semiconductor structure. The intermediate semiconductor structure may be formed after forming a plurality of openings in a substrate, but before annealing the substrate. The intermediate semiconductor structure may include a substrate including a plurality of openings. The plurality of openings may extend from a surface of the substrate into the substrate. Each of the plurality of openings may at least partially be defined by a side wall and may include a portion closer to the surface of the substrate and another portion further away from the surface of the substrate. A diameter or lateral dimension of at least one of the plurality of openings may increase with distance from the surface of the substrate such that the portion closer to the surface of the substrate of said at least one of the plurality of openings is narrower than the other portion further away from the surface of the substrate of said at least one of the plurality of openings.

In various embodiments, each of the plurality of openings may include a bottom surface such that the side wall extends between the surface of the substrate and the bottom surface.

In various embodiments, the bottom surface of each of the plurality of openings and a cross-sectional area of each of the plurality of openings at the surface of the substrate may be of a circular, hexagonal or square shape.

In various embodiments, the side wall defining said at least one of the plurality of openings may form an angle in a range of greater than 90° to smaller than 120° with respect to the surface of the substrate.

In various embodiments, a diameter or lateral dimension of one or more remaining openings of the plurality of openings may increase with distance from the surface of the substrate. The portion closer to the surface of the substrate of each of the one or more remaining openings may be narrower than the other portion further away from the surface of the substrate of each of the one or more remaining openings.

In various embodiments, a diameter or lateral dimension of each opening of the plurality of openings may increase with distance from the surface of the substrate (such that the portion closer to the surface of the substrate (i.e. the upper part) of each of the plurality of openings is narrower than the other portion further away from the surface of the substrate (i.e. the lower part) of each of the plurality of openings). Each of the plurality of openings may substantially be of a frustum shape.

In various embodiments, an aspect ratio of a depth of each of the plurality of openings relative to a diameter or lateral dimension of each of the plurality of openings at the surface of the substrate may be selected from a range of greater than 13 to smaller than 25.

In various embodiments, the plurality of openings may be equally spaced apart.

In various embodiments, a group of three neighboring or adjacent openings of the plurality of openings may be arranged so as to form an equilateral triangle (as seen from a planar view of the surface of the substrate). In various other embodiments, a group of four neighboring or adjacent openings may be arranged so as to form a square or diamond (as seen from a planar view of the surface of the substrate).

In various embodiments, the plurality of openings may be formed such that the plurality of openings merge together to form a cavity. In other words, the lower part(s) of at least one of the plurality of openings may be overlapped with the lower part(s) of at least another of the plurality of openings neighboring or adjacent to the at least one of the plurality of openings.

In various embodiments, a spacing between neighboring or adjacent openings may be equal to or greater than a diameter or lateral dimension of each of the plurality of openings at the surface of the substrate. Various embodiments may relate to an intermediate semiconductor structure formed by a method as described herein.

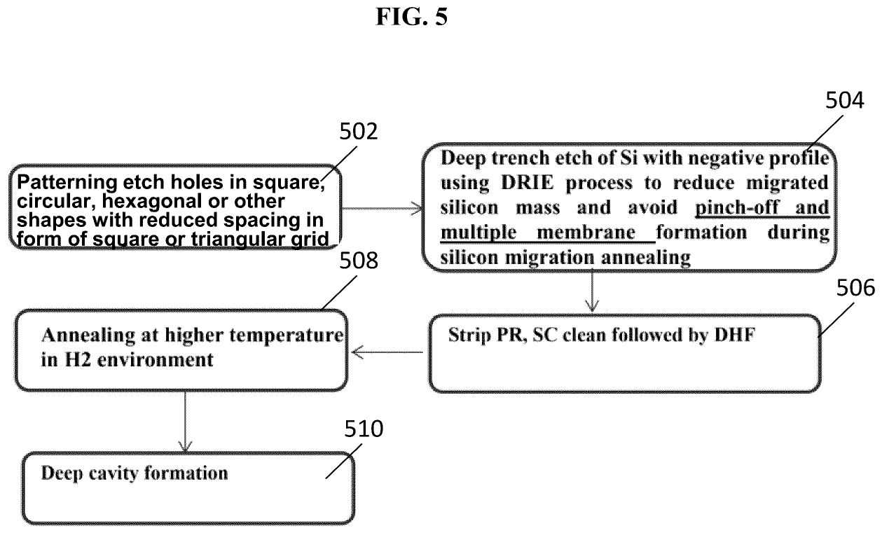

FIG. 5 illustrates a process of forming a semiconductor structure having a buried deep cavity using a silicon-on-nothing (SON) technique according to various embodiments. The semiconductor structure may be a silicon (Si) substrate with a silicon membrane and the buried cavity (or deep cavity). In step 502, photo resist (PR) with square or triangular grids of square, circular, or hexagonal openings or openings of other shapes may be used as a mask to reduce and equalize the volume of silicon to be migrated from the openings (or deep trenches) to the membrane. In step 504, these negative etched holes may be formed in silicon using DRIE. The negative profile of etch holes may help in avoiding the pinch-off and multiple membrane formation during silicon migration (observed during deep vertical hole etching and annealing) as well as help in reducing mass of silicon to be migrated into membrane to get a deeper buried cavity. The merging of neighboring negative profile openings (i.e. truncating of the spacings between lower parts of neighboring openings) during etching may help silicon migration in the preferred upwards direction into the membrane, while reducing or preventing silicon migration downwards. In step 506, the photoresist (PR) may be stripped, followed by substrate cleaning (SC) using standard wafer cleaning steps (referred to as RCA clean) and diluted hydrofluoric acid (DHF). In step 508, the silicon substrate may be annealed at a higher temperature to form the buried cavity (i.e. deep cavity) in step 510. The annealing may allow the migration of the silicon to form the membrane over the buried cavity.

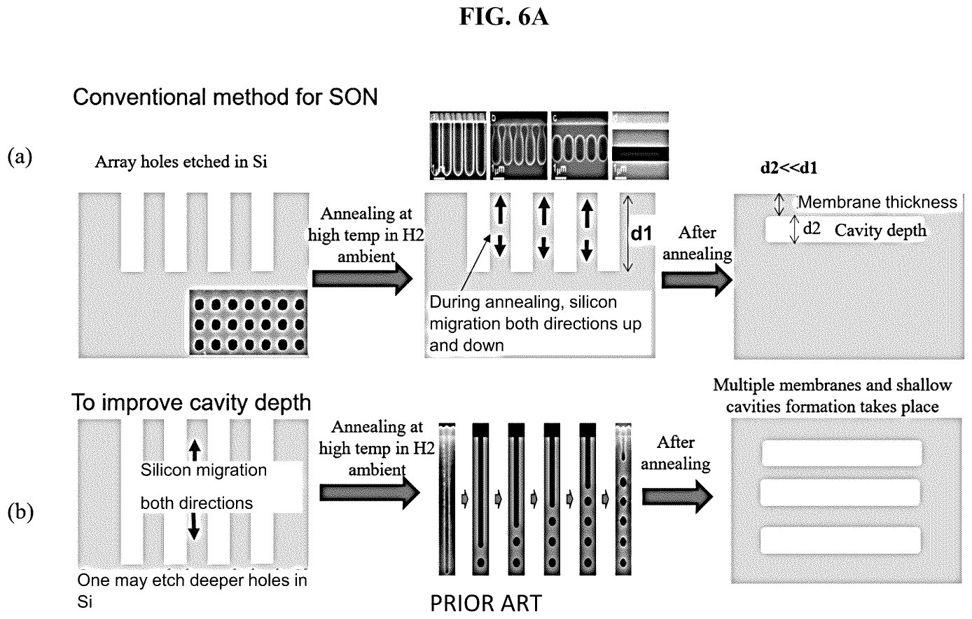

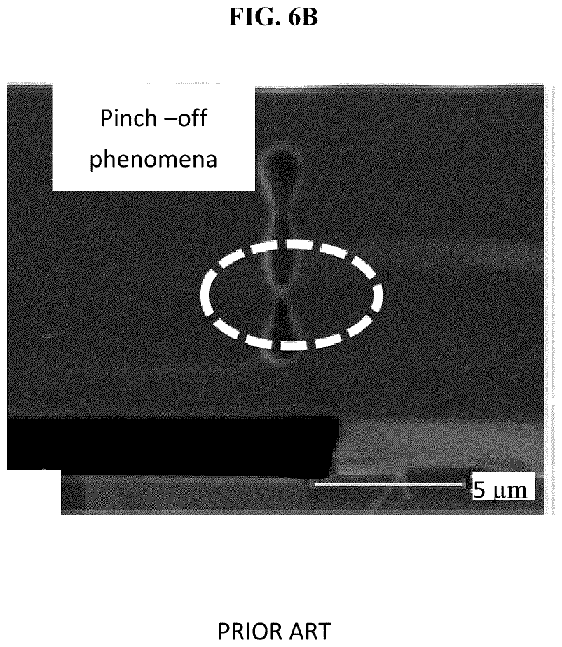

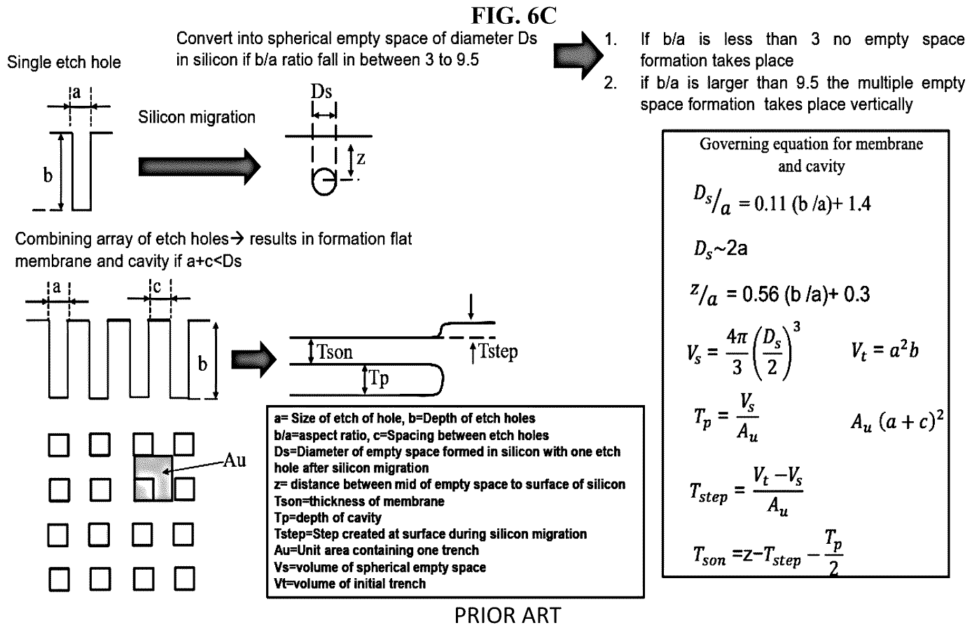

FIG. 6A illustrates conventional processes of forming silicon-on-nothing (SON) structures. In the conventional process, an array of etch holes is etched vertically into the silicon. The annealing of the array of holes in silicon at high temperature in hydrogen, argon or nitrogen environment results in migration of silicon atoms in both up and down directions. Consequently, a thick membrane and a shallow buried cavity is formed. One may think of reducing the spacings between etch holes and etching deeper holes etching to get a deeper cavity formation during the silicon migration. However, doing so would result in a pinch-off phenomenon during silicon migration causing formation of multiple membranes and multiple small cavities. FIG. 6B is a scanning electron microscopy (SEM) image showing the pinch-off phenomenon. FIG. 6C illustrates the relevant equations that result in the formation of multiple membranes and multiple small cavities in the conventional silicon-on-nothing (SON) process.

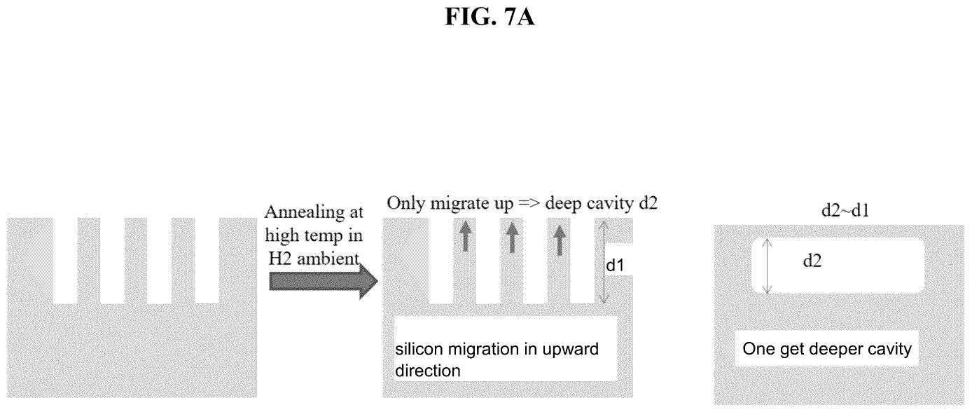

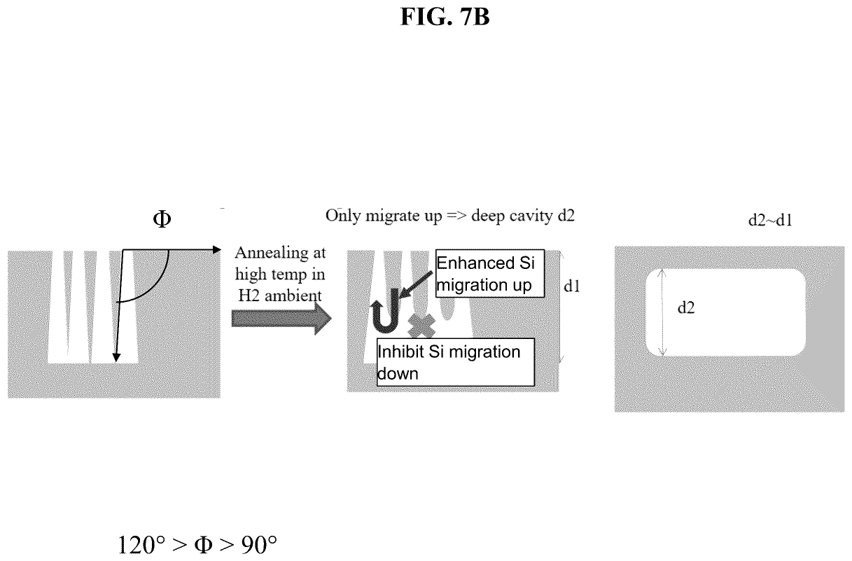

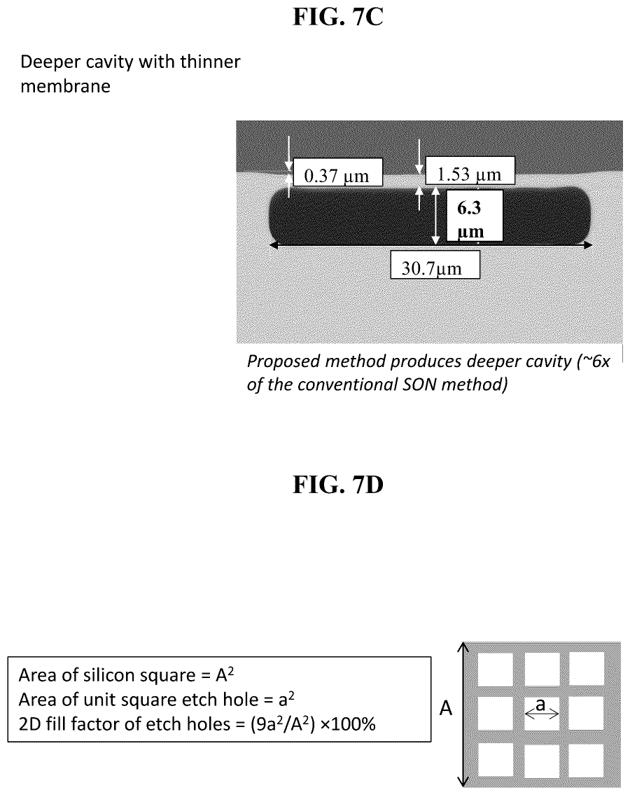

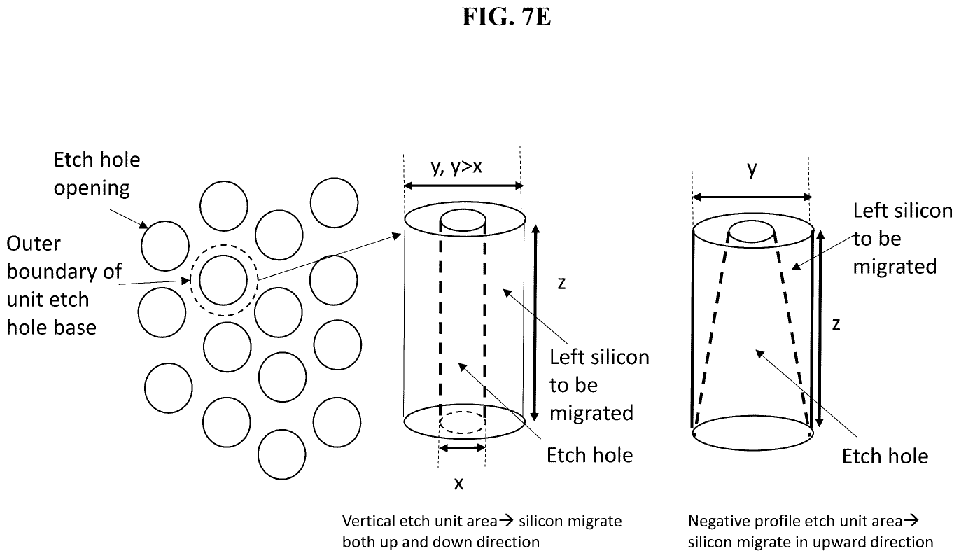

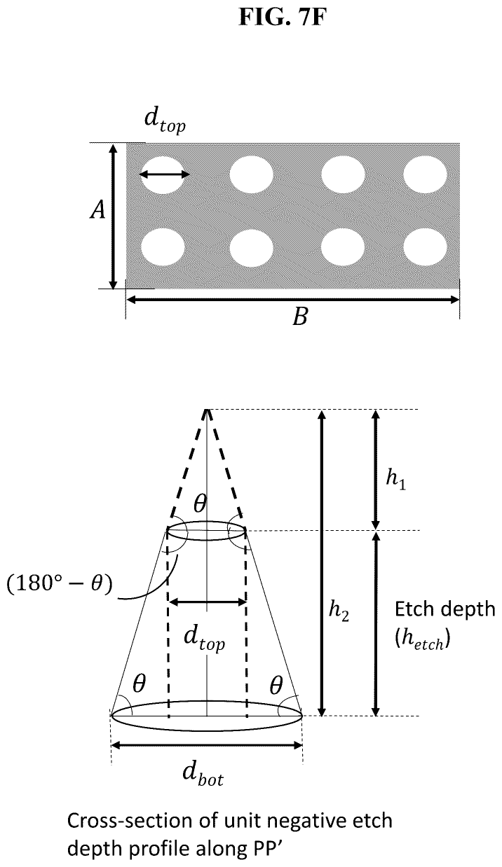

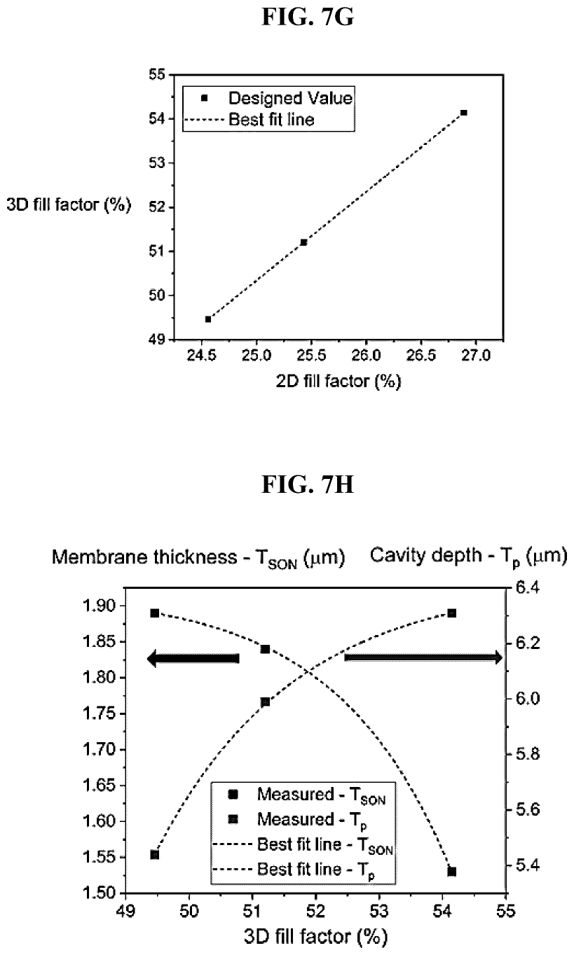

FIG. 7A illustrates an ideal case to obtain deeper cavities using the silicon-on-nothing (SON) technique. In this ideal case, only upwards silicon migration should occur. FIG. 7B illustrates a process of forming a semiconductor structure having a deeper buried cavity using a silicon-on-nothing (SON) technique involving forming openings with negative profile according to various embodiments. The negative profile of openings in the silicon substrate using DRIE may enhance the silicon migration in upward direction and may inhibit or reduce the silicon migration in the downward direction during annealing. It can be seen from FIG. 7B that the diameters or lateral dimensions of the openings may increase with distance from the surface of the substrate. In various embodiments, the diameters or lateral dimensions of the openings may increase in a substantially linear manner with distance from the surface of the substrate. Consequently, the semiconductor structure formed may have a deep buried cavity. In various embodiments, the buried cavity may have a height of more than 3 μm or 3.5 μm, e.g. about 5 μm to 6 μm or more. In various embodiments, the thickness of the membrane above the buried cavity may be selected from a range from 1 μm to 3 μm, e.g. from 1.5 μm to 1.7 μm. In various embodiments, as shown in FIG. 7B, the side wall defining said at least one of the plurality of openings may form an angle (Φ) in a range of greater than 90° to smaller than 120° (i.e. 120°>Φ>90°) with respect to the surface of the substrate.

FIG. 7C shows a scanning electron microscopy (SEM) image of a semiconductor structure with a buried deep cavity and a membrane over the buried deep cavity according to various embodiments. Various embodiments may relate to using a combination of an array of openings (etch holes) on silicon surface arranged in a specific grid pattern, and negative profile etching using DRIE process to allow formation of deep cavity with pre-released silicon membrane on top when exposed to annealing under high temperature and high vacuum. This process may be driven by the surface diffusion of silicon and may be known as SON/silicon migration process. The array of etch holes may determine the 2-dimensional (2D) fill factor of etch holes on surface of the bulk-silicon wafer. Given the angle and depth of negative DRIE etch hole profile may contribute to the volume of silicon to be migrated, varying the 2D fill factor with different geometries and sizes of etch holes on the silicon surface may allow a broad range of cavity depths under a thin silicon membrane as compared to limited cavity depths associated with conventional SON processes. FIG. 7D illustrates the calculation of 2-dimensional (2D) fill factor of an array of square etch holes according to various embodiments.

FIG. 7E illustrates a comparison of migrated silicon volume for vertically etched circular openings (holes) and circular base (holes) of a negative profile according to various embodiments. Calculations show that the vertically etched profile holes have about 2 times more silicon (Si) to be migrated as compared to the negative etch profile holes.

There may be ~24.5% discrepancy between the initial volume of Si etched during DRIE and the cavity formed. Such discrepancy may be associated to one or more of the followings: (1) due to the formation of step (with a height of 0.37 μm), the Si membrane surface may be lower than the surface of the remaining Si substrate; (2) due to scallops along the sidewalls of the trenches; and (3) due to rounding of corners after the SON process.

FIG. 7F illustrates an unit cell to compute a 3-dimensional (3D) fill factor based on the 2-dimensional (2D) fill factor, etch depth and angle of negative etch profile according to various embodiments. (180°−θ) represents the angle for negative etch profile.

3D fill factor of etch holes can be represented as a function of 2D fill factor of etch holes (2DFF_{etchholes}), etch depth (h_{etch}), and angle of negative etch profile (180°−θ).

It may be noted that for a particular 3D fill factor of etch holes, there may be multiple combinations of 2D fill factor of etch holes (2DFF_{etchholes}), etch depths (h_{etch}), and angles of negative etch profile (180°−θ).

FIG. 7G shows a plot of the 3-dimensional fill factor 3DFF_{etchholes} (in percent or %) as a function of the 2-dimensional fill factor 2DFF_{etchholes} (in percent or %) illustrating variation of 3DFF_{etchholes} with 2DFF_{etchholes} of the openings according to various embodiments.

FIG. 7H shows a plot of membrane thickness Tₛₒₙ (in micrometers or μm)/cavity depth Tₚ (in micrometers or μm) as a function of the 3-dimensional fill factor 3DFF_{etchholes} (in percent or %) illustrating variations of Tₛₒₙ and Tₚ with 3DFF_{etchholes} of the openings according to various embodiments. It can be seen from FIG. 7H that Tₛₒₙ decreases exponentially with increase in 3DFF_{etchholes}, while Tₚ increases exponentially with 3DFF_{etchholes}.

In various embodiments, the 3D fill factor of the openings (3DFF_{etchholes}) may be between 40% and 60%, i.e. 40%<3DFF_{etchholes} <60%.

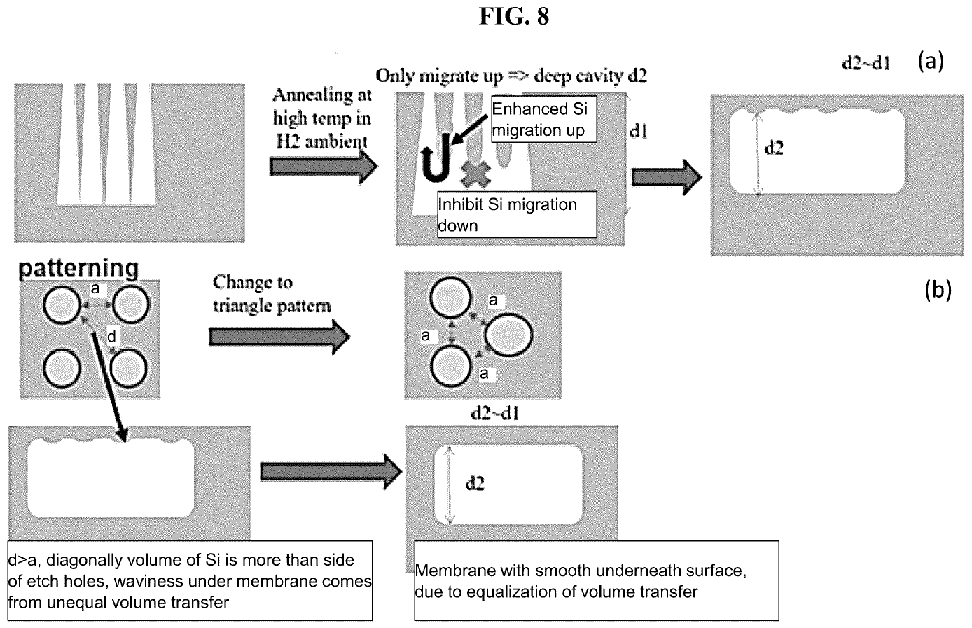

FIG. 8 illustrates (a) a process of forming a semiconductor structure according to various embodiments; and (b) a comparison between the semiconductor structures formed using a square array of openings and an equilateral triangular array of openings according to various embodiments. A square array of openings (etch holes) may mean that there is a larger mass of silicon between diagonal pairs of openings than sideway pairs of openings to migrate upwards, which may cause the underneath surface of the membrane (i.e. the surface of the membrane at least partially defining the buried cavity) to be wavy. In contrast, a triangular array of openings may result in a membrane with a smoother underneath surface. This may be due to the equalization of silicon migration in all directions of the openings or etch holes.

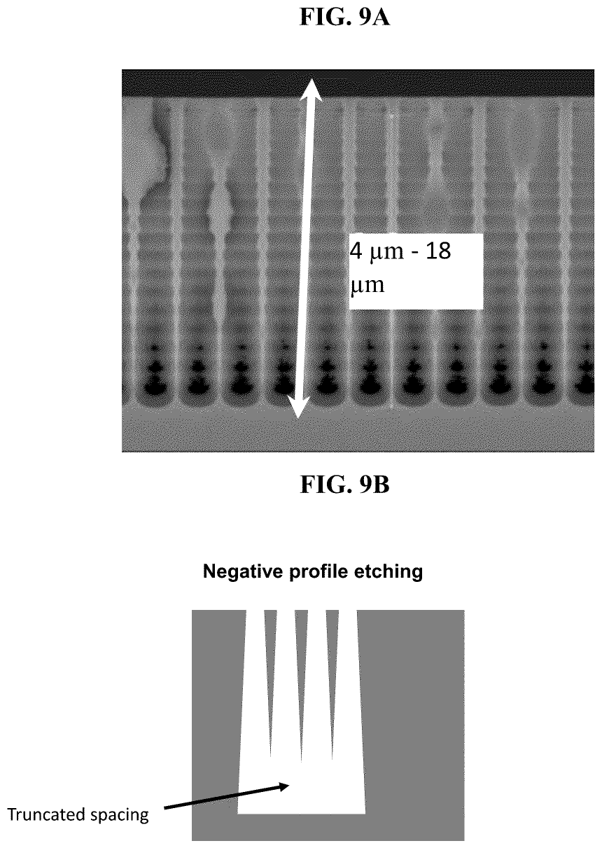

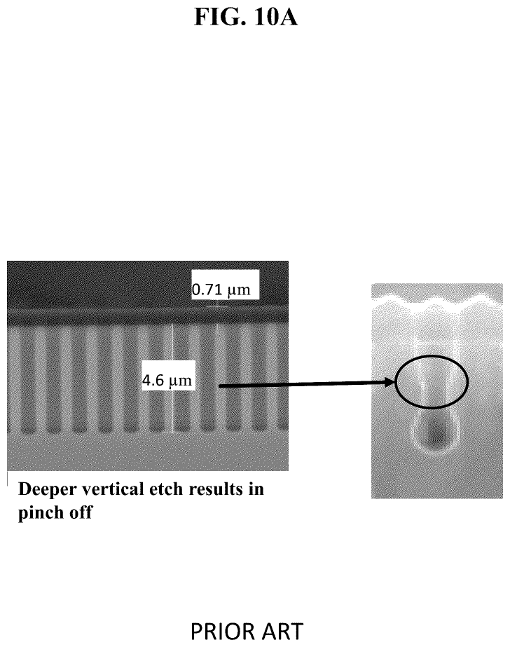

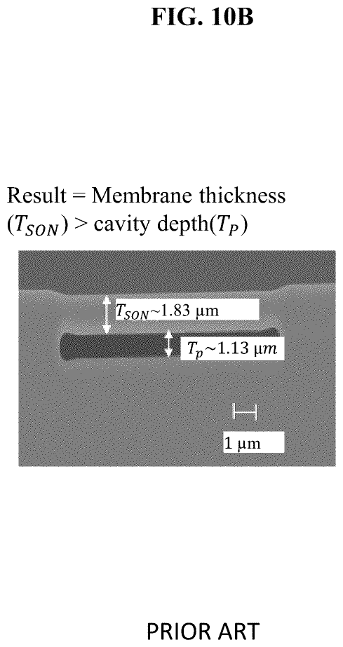

FIG. 9A shows a scanning electron microscopy (SEM) image illustrating experimental results of negative profile silicon etching according to various embodiments. It can be observed from FIG. 9A that etch holes merged downside due to negative profile etching. FIG. 9B shows a schematic illustrating the merging of the etch holes according to various embodiments. The SEM image showing the formed buried cavity after annealing is presented in FIG. 7C. As highlighted earlier, the buried cavity and overlying membrane formed after annealing of silicon wafer in hydrogen (H₂), argon (Ar) and/or nitrogen (N₂) ambient at higher temperature may be due to silicon migration. For samples fabricated, the Si membrane thickness and depth of cavity were measured to be 1.5 μm to 1.7 μm and 5.5 μm to 6.64 μm. respectively. In contrast, the cavity depths reported in literature for conventional SON processes are in the range of between 1 μm and 3 μm. SEM images showing the vertical etched holes and the resulting buried cavity formed using the convention SON process are presented in FIGS. 10A-B. FIG. 10A is a scanning electron microscopy (SEM) image showing the pinch-off phenomenon. FIG. 10B is a scanning electron microscopy (SEM) image showing a conventional silicon-on-nothing structure.

Various embodiments may relate to a method of forming a semiconductor structure in which the ratio of the thickness of the membrane to the buried cavity is <1. In contrast, in reported literature, the ratio of the thickness of the membrane to the buried cavity is >1.

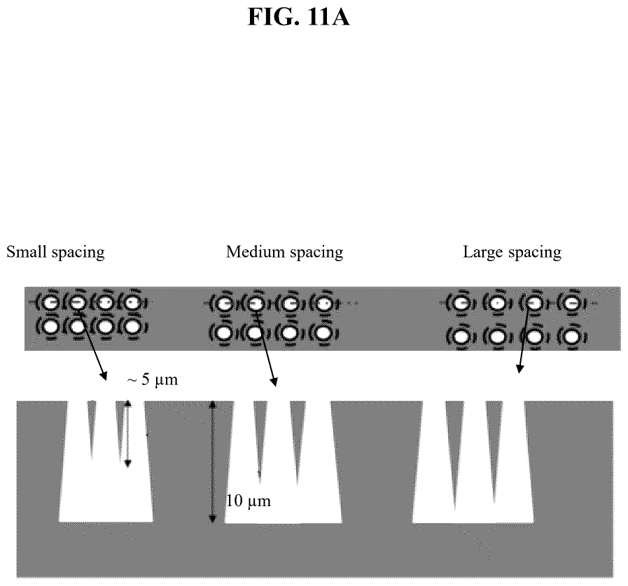

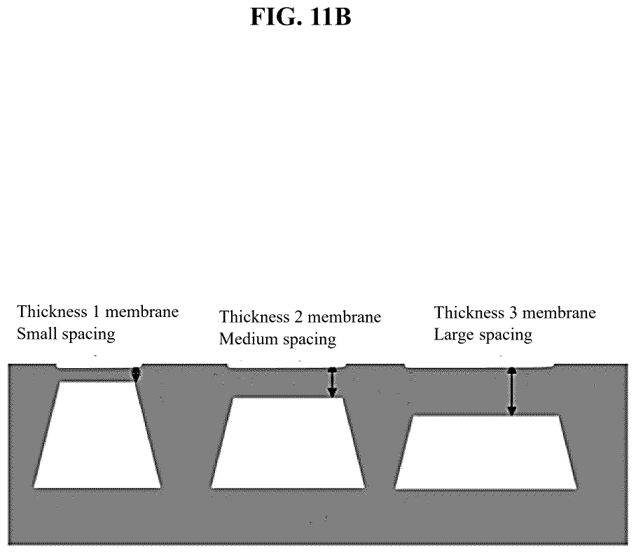

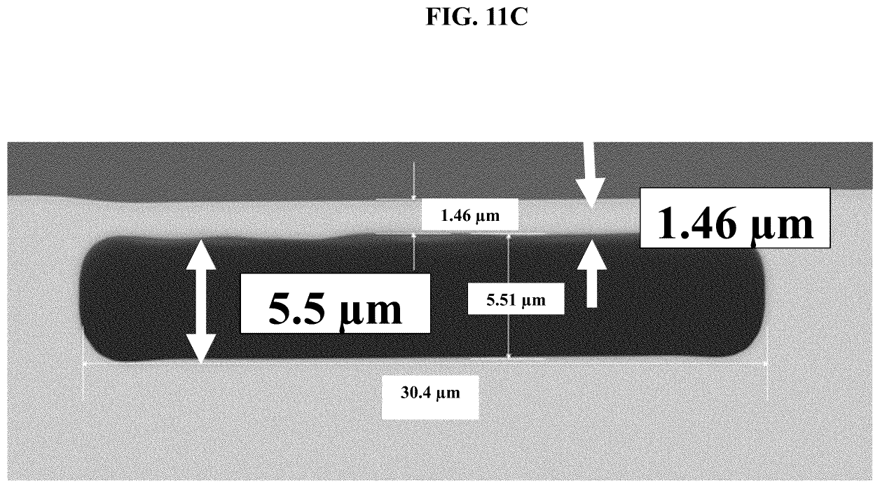

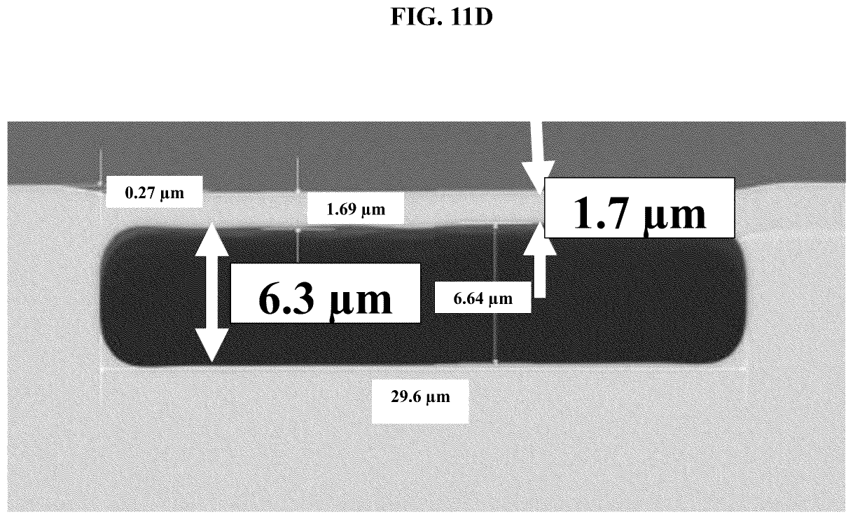

Alternatively, many MEMS applications may need different thicknesses of membranes and different heights of deep cavities to be simultaneously formed on a single substrate or wafer. This may be achieved by etching silicon to form openings (etch holes) with negative profile and having the same diameters but with different spacings between neighboring or adjacent openings (etch holes). This may help in the truncation of spaces between the neighboring or adjacent openings (etch holes) at different depths. In other words, by adjusting the spacing between the neighboring or adjacent openings (etch holes) on the surface of the substrate, the merging of the neighboring or adjacent openings (etch holes) may be controlled to occur at different distances from the surface of the substrate. FIG. 11A shows a schematic of the substrate in which negative profile openings (holes) are formed with different spacings between neighboring or adjacent openings (holes), leading to merging of the openings (holes) at different depths according to various embodiments. As the amounts of migrated silicon for subsequent formation of the membranes are different for groups of openings (holes) with different spacings, the membranes formed subsequently may be different as shown in FIG. 11B. FIG. 11B shows a schematic of the substrate with different thicknesses of membranes formed corresponding to the different groups of openings (holes) with different spacings according to various embodiments.

FIG. 11C shows a scanning electron microscopy (SEM) image of the semiconductor structure formed from openings (holes) with small pitch according to various embodiments. FIG. 11D shows a scanning electron microscopy (SEM) image of the semiconductor structure formed from openings (holes) with medium pitch according to various embodiments. The pitch may refer to a distance between a center of an opening to a center of a neighboring or adjacent opening. It may be seen from the SEM images that by changing the pitch and design of the openings (holes), structures with different membrane thicknesses and buried cavity depths may be formed. In various embodiments the pitch may be any value selected from a range from 0.4 μm to about 1.0 μm. Various embodiments may allow for structures with thicker membranes with increased cavity depths. Structures with thicker membrane may be less sensitive to initial pressure difference.

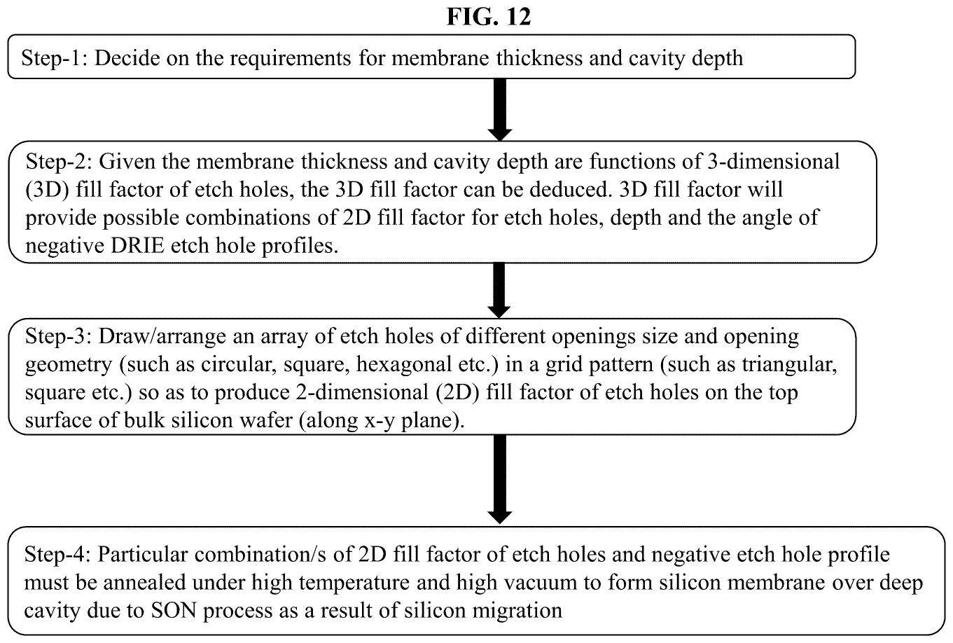

FIG. 12 shows the steps involved in the design of a semiconductor structure including a buried cavity and a membrane above the buried cavity according to various embodiments.

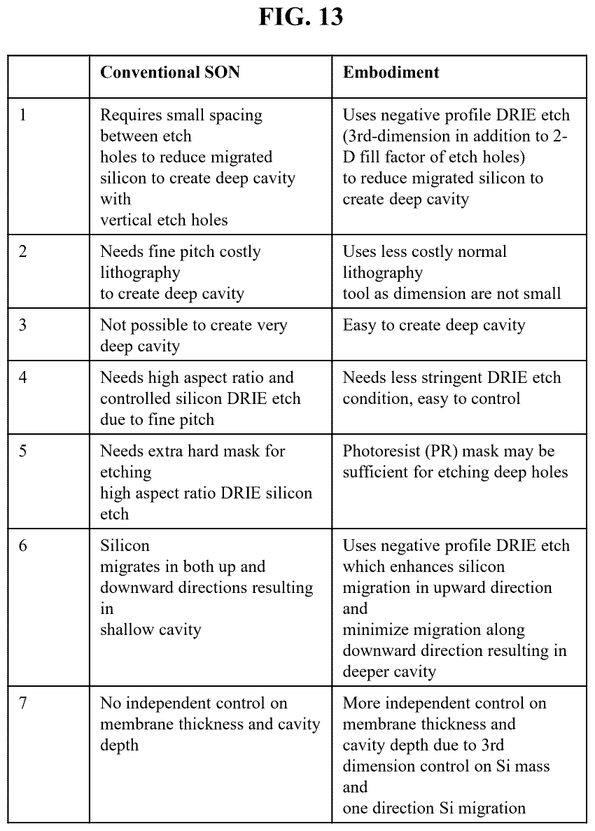

FIG. 13 shows a table comparing the conventional silicon-on-nothing (SON) process and various embodiments.

Various embodiments may involve use of a negative profile etch (i.e. negatively-tapered etch) for defining the plurality of openings (i.e. holes or trenches) before forming the membrane via annealing. Compared to conventional vertical etching followed by subsequent annealing, in the negatively-tapered etch (when taper angle is sufficient), silicon may migrate only upwards not downwards, thereby preventing the pinch-off which causes formation of multiple membranes and multiple small cavities. The migration of silicon upwards (and not downwards) may allow for deeper buried cavities to be formed. The negatively-tapered etching of the plurality of openings with different spacings between openings may cause the truncation of the holes at different depths, resulting in different thicknesses of the membranes formed (upon annealing). This phenomenon may be due to the minimization of surface area of the silicon to reach lower energy states.

Various embodiments may relate to a substrate including an array of deep etch holes with negative DRIE profile (where the angle between surface of substrate to the side wall of etch hole can be larger than 90° and smaller than) 120° and aspect ratio (ratio between depth of etch hole to etch hole opening) larger than 13 and smaller than 25. The etch holes may merge at bottom to create an initial cavity and enhance silicon migration in upward direction towards silicon surface. The array of etch holes arranged in a specific grid pattern on the surface of the substrate may determine the 2D fill factor of the etch holes. According to various embodiments, within a specific grid, etch holes may be equally spaced apart and the ratio between etch hole opening to spacing between etch holes can be equal to or larger than 1. The ratio between depth of etch hole to the opening of etch hole may be larger than 13 and smaller than 25.

The 2D fill-factor of etch holes in combination with angle and depth of negative profile DRIE etch holes may constitute a 3-dimensional (3D) fill-factor. The 3D fill-factor can be larger than 40% and smaller than 60% to produce embedded deep cavity with pre-released thin membrane in silicon substrate. For a particular 3D fill factor, there can be multiple combinations of 2D fill factor of etch holes, angles of negative profile DRIE etch holes, and the etch depths.

The silicon substrate may have a resistivity greater than 0.1 Ohms-centimeter ((2-cm).

Given the angle and depth of negative DRIE etch hole profile are dependent on the 2D fill-factor, varying the 2D fill factor with different geometries and sizes of etch holes on the silicon surface may allow a broad range of cavity depths under a thin silicon membrane as compared to limited cavity depths with conventional SON process within a single fabrication run.

The negative DRIE profile of such etch holes may produce gradually reducing silicon mass towards the downside or bottom part of the etch holes, resulting in deep cavity formation without pinch-off due to silicon migration. Such pinch-off may result in multiple cavities along vertical (where the angle between surface of substrate to the side wall of etch hole is equal to) 90° and long etch holes as seen among conventional SON process. According to various embodiments, the depth of the embedded cavity may be larger than 3.5 μm, while for the conventional SON fabrication method, the depth of embedded cavity may be equal to or lower than 1 μm.

According to various embodiments, etch holes with such negative DRIE profile (along z-axis) with control of the 2D fill factor of etch holes along the top surface (in x-y plane) may result in a semiconductor structure having a silicon membrane with deep cavity underneath formed by SON/silicon migration process upon annealing under high temperature and high vacuum level.

In a conventional SON fabrication method, only the 2D fill factor (along x-y plane) can be tuned to obtain thinner membrane with deeper cavity. There is no control over the amount of Si along the thickness direction (z-axis) as holes are vertically etched, where the angle between surface of substrate and side wall of etch hole is 90°. In contrast, in various embodiments, both 2D fill factor (along x-y plane) and amount of Si along thickness direction (z-axis) may be tuned to fabricate thinner membrane with deeper cavity. The amount of Si along thickness direction (z-axis) may be controlled by the negative profile DRIE etch, where the angle between surface of substrate and side wall of etch hole can be larger than 90° and smaller than 120°.

In a conventional SON fabrication method, the post-SON cavity depth (i.e. height of buried cavity) in silicon may be governed by conventional migration equations due to the regular distribution of Si along the vertical DRIE profile. In contrast, in various embodiments, the post-SON cavity depth may not be governed by conventional migration equations as the Si distribution does not remain regular due to negative etch profile.

In a conventional SON fabrication method, Si around the deep etch holes migrates along both upward and downward directions. Due to the regular distribution of Si along the depth of etch holes, only shallower cavities (e.g. ≤1 μm) may be formed. In contrast, in various embodiments, the silicon migration upwards may be enhanced due to the gradual increase of etched area in conical shape and merging of etch holes at bottom due to negative profile DRIE etch while the migration of Si along downward direction may be inhibited. This may result in a deeper cavity (e.g. >3.5 μm).

Further, a conventional SON fabrication method may need critical dimension (CD) of very small spacing between vertical etch holes for reducing migrated silicon to create deep cavity. Defining a small CD may need lithography to be done in costly lithography tool such as electron beam (E-beam) lithography. In contrast, in various embodiments, normal lithography tool may be sufficient as CD is not be required to be very small to obtain deep cavities.

1. A method for forming a semiconductor structure, the method comprising:
forming a plurality of openings in a substrate, wherein the plurality of openings extend from a surface of the substrate into the substrate, wherein each of the plurality of openings is at least partially defined by a side wall and comprises a portion closer to the surface of the substrate and another portion further away from the surface of the substrate, and wherein a diameter or lateral dimension of at least one of the plurality of openings increases with distance from the surface of the substrate such that the portion closer to the surface of the substrate of said at least one of the plurality of openings is narrower than the other portion further away from the surface of the substrate of said at least one of the plurality of openings; and
annealing the substrate after forming the plurality of openings, thereby forming a buried cavity and a membrane over the buried cavity, the buried cavity having a height greater than 3 μm and greater than a thickness of the membrane.

2. The method of claim 1,
wherein each of the plurality of openings comprises a bottom surface such that the side wall extends between the surface of the substrate and the bottom surface.

3. The method of claim 2,
wherein the bottom surface of each of the plurality of openings and a cross-sectional area of each of the plurality of openings at the surface of the substrate are of a circular, hexagonal or square shape.

4. The method of claim 2,
wherein the bottom surface has a size at least 1.5 times greater than a size of the opening at the surface of the substrate.

5. The method of claim 1,
wherein the side wall defining said at least one of the plurality of openings forms an angle in a range of greater than 90° to smaller than 120° with respect to the surface of the substrate.

6. The method of claim 1,
wherein a diameter or lateral dimension of one or more remaining openings of the plurality of openings increases with distance from the surface of the substrate.

7. The method of claim 1,
wherein each of the plurality of openings is substantially of a frustum shape.

8. The method of claim 1,
wherein an aspect ratio of a depth of each of the plurality of openings relative to a diameter or lateral dimension of each of the plurality of openings at the surface of the substrate is selected from a range of greater than 13 to smaller than 25.

9. The method of claim 1,
wherein a group of three neighboring openings of the plurality of openings are arranged so as to form an equilateral triangle.

10. The method of claim 1,
wherein a group of four neighboring openings of the plurality of openings are arranged so as to form a square or diamond.

11. The method of claim 1,
wherein the plurality of openings are equally spaced apart.

12. The method of claim 1,
wherein annealing the substrate comprises annealing such that atoms from the substrate migrate to form the membrane.

13. The method of claim 1,
wherein the thickness of the membrane formed is dependent on a depth of the plurality of openings, a diameter or lateral dimension of the plurality of openings, an angle between the surface of the substrate and side walls of the plurality of openings, and a spacing between neighboring openings of the plurality of openings.

14. The method of claim 1,
wherein the height of the buried cavity formed is dependent on a depth of the plurality of openings, a diameter or lateral dimension of the plurality of openings, an angle between the surface of the substrate and the side walls of the plurality of openings, and a spacing between neighboring openings of the plurality of openings.

15. The method of claim 1,
wherein the height of the buried cavity is greater than half of a depth of the plurality of openings.

16. The method of claim 1,
wherein the plurality of openings are formed such that the plurality of openings merge together to form a cavity.

17. The method of claim 1,
wherein a spacing between neighboring openings is equal to or greater than a diameter or lateral dimension of each of the plurality of openings at the surface of the substrate.

18. The method of claim 1,
wherein the semiconductor structure is a silicon-on-nothing (SON) structure.

19. The method of claim 1,
wherein a portion of the surface of the substrate at least partially defining the membrane is recessed from a remaining portion of the surface of the substrate.

20. A semiconductor structure comprising:
a substrate having a buried cavity and a membrane over the buried cavity;
wherein the buried cavity has a height greater than 3 μm and greater than a thickness of the membrane.
